(19) United States
(12) Patent Application Publication
(10) Pub. No.: US 2024/0306390 A1
(43) Pub. Date: Sep. 12, 2024

(54) SEMICONDUCTOR STORAGE DEVICE

(71) Applicant: Kioxia Corporation, Tokyo (JP)

(72) Inventors: Shinya NAITO, Toyota Aichi (JP); Takayuki KAKEGAWA, Yokkaichi Mie (JP); Kenji KAWABATA, Yokkaichi Mie (JP); Eri SAHARA, Nagoya Aichi (JP)

(21) Appl. No.: 18/595,335

(22) Filed: Mar. 4, 2024

(30) Foreign Application Priority Data
Mar. 8, 2023 (JP) 2023-035751

(51) Int. Cl. H10B 43/27; H10B 41/27

(52) U.S. Cl. CPC H10B 43/27; H10B 41/27

(57) ABSTRACT

A semiconductor storage device includes a substrate, a wiring layer region on the substrate, a stacked body on the wiring layer region and in which conductive layers and insulating layers are alternately stacked in a first direction, and a columnar portion that includes a semiconductor body extending in the first direction through the stacked body and into the wiring layer region and a charge storage film surrounding the semiconductor body. The columnar portion includes a first columnar portion positioned at an end portion of the stacked body, a second columnar portion in the wiring layer region, and a connection portion between the first and second columnar portions. The semiconductor body in the connection portion has a first portion extending in a second direction, and the charge storage film in the connection portion has a second portion extending in the second direction and covers the first portion in the first direction.

### CROSS-REFERENCE TO RELATED APPLICATION(S)

This application is based upon and claims the benefit of priority from Japanese Patent Application No. 2023-035751, filed Mar. 8, 2023, the entire contents of which are incorporated herein by reference.

### FIELD

Embodiments described herein relate generally to a semiconductor storage device.

### BACKGROUND

A three-dimensional memory device, which has a stacked body in which a plurality of conductive layers and a plurality of insulating layers are stacked and a plurality of columnar portions penetrating the stacked body in a thickness direction, is known.

### DESCRIPTION OF THE DRAWINGS

FIG. 1 is a schematic plan view showing a semiconductor storage device of a first embodiment.

FIG. 2 is a schematic plan view showing a cell array region of the semiconductor storage device of the first embodiment.

FIG. 3 is a schematic perspective view showing the cell array region of the first embodiment.

FIG. 4 is a sectional view taken along line A-A′ including a stacked body and a columnar portion shown in FIG. 2.

FIG. 5 is a partially enlarged sectional view of the columnar portion in FIG. 4.

FIG. 6 is a sectional view taken along line D-D′ of the stacked body and the columnar portion shown in FIG. 5.

FIG. 7 is a partial sectional view showing the stacked body, the columnar portion, and a wiring layer region shown in FIG. 4.

FIG. 8 is a partial sectional view showing the stacked body, the columnar portion, and the wiring layer region shown in FIG. 7.

FIGS. 9-22 are sectional views showing parts of a method of manufacturing an example structure of the first embodiment.

FIG. 23 is a partial sectional view showing an example of a stacked body, a columnar portion, and a wiring layer region of a second embodiment.

FIG. 24 is a sectional view showing another example of a stacked body, a columnar portion, and a wiring layer region of a third embodiment.

FIG. 25 is a partial sectional view showing an example of a lower end portion of the columnar portion and a lower end portion of an insulating portion of the third embodiment.

FIG. 26 is a partial sectional view showing a relationship between an MH deviation amount and a threshold voltage.

### DETAILED DESCRIPTION

Embodiments provide a semiconductor storage device capable of improving electrical characteristics.

In general, according to one embodiment, a semiconductor storage device includes a substrate, a wiring layer region provided on the substrate, a stacked body that is provided on the wiring layer region and in which a plurality of conductive layers and a plurality of insulating layers are alternately stacked in a first direction, and a columnar portion that extends in the first direction through the stacked body and into the wiring layer region, the columnar portion including a semiconductor body extending in the first direction through the stacked body and into the wiring layer region and a charge storage film surrounding the semiconductor body and extending in the first direction through the stacked body and into the wiring layer region. The stacked body has an end portion in the first direction facing the wiring layer region. The columnar portion includes a first columnar portion positioned at the end portion of the stacked body, a second columnar portion provided in the wiring layer region, and a connection portion between the first columnar portion and the second columnar portion. The semiconductor body in the connection portion has a first extending portion that extends in a second direction crossing the first direction, and the charge storage film in the connection portion has a second extending portion that extends in the second direction and covers the first extending portion in the first direction.

### First Embodiment

Hereinafter, the semiconductor storage device of the first embodiment will be described with reference to the drawings.

In the following description, configurations having the same or similar functions are designated by the same reference numerals. Also, the duplicate description of those configurations may be omitted. In the present application, the term “connection” is not limited to the case of being physically connected, but also includes the case of being electrically connected. In the present application, “xx faces yy” is not limited to the case where xx is in contact with yy, but also includes the case where another member is interposed between xx and yy. In the present application, “xx is provided on yy” is not limited to the case where xx is in contact with yy, but also includes the case where another member is interposed between xx and yy. In addition, in the present application, “xx is provided on yy” is an expression for convenience and does not specify the direction of gravity. In the present specification, the terms “parallel” and “orthogonal” also include when being “substantially parallel” and “substantially orthogonal”, respectively.

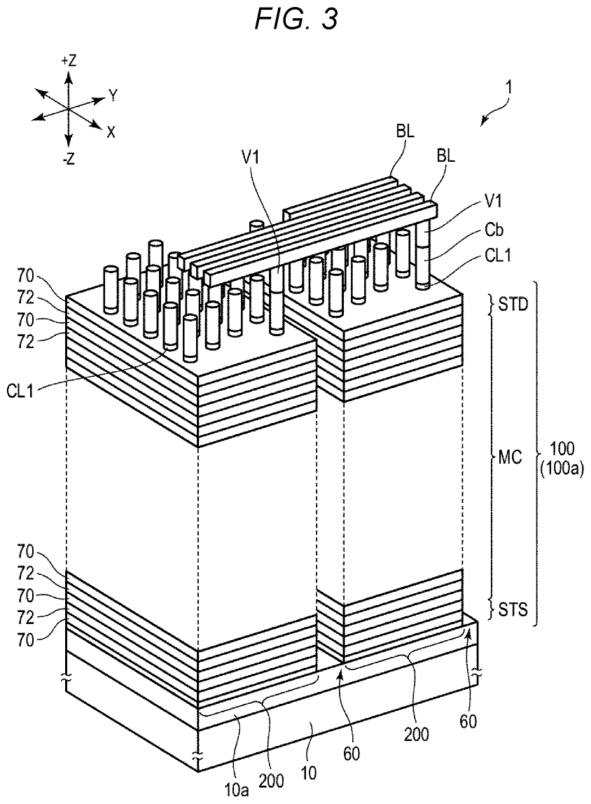

Further, an X direction, a Y direction, and a Z direction are defined first. The X direction and the Y direction are directions along a surface of a substrate 10 (see FIG. 3) described later. The X direction and the Y direction are directions that intersect with each other (for example, are orthogonal to each other). The Y direction is a direction in which the bit line BL (refer to FIG. 3) that will be described later extends. The Z direction is a direction that intersects (for example, is orthogonal to) the X direction and the Y direction, and is a thickness direction of the substrate 10. In the present specification, as shown in FIG. 3, the “+Z direction” may be referred to as “up” and the “−Z direction” may be referred to as “down”. The +Z direction and the −Z direction are 180° different from each other. Here, these expressions are for convenience only and do not specify the direction of gravity.

### Overall Configuration of Semiconductor Storage Device

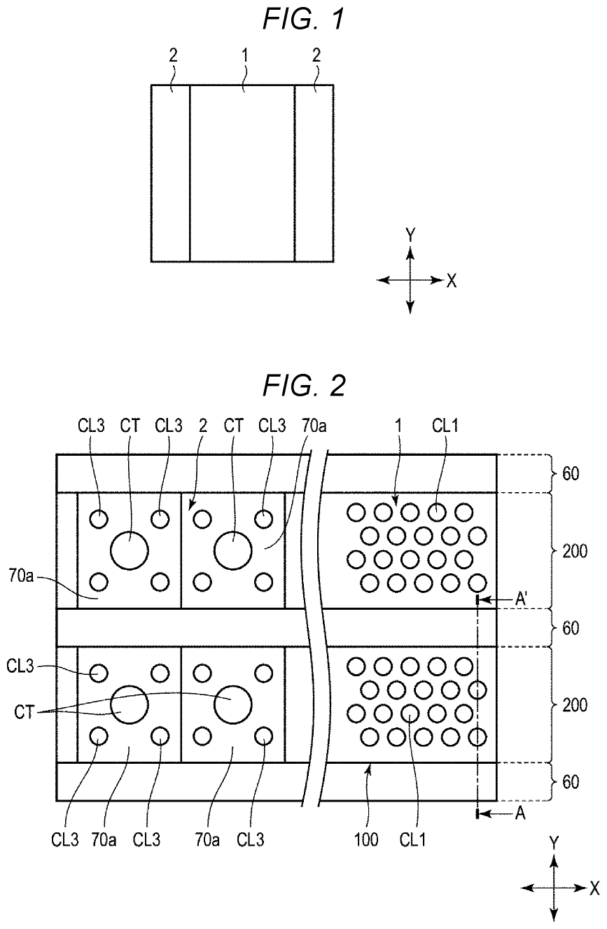

FIG. 1 is a schematic plan view showing a semiconductor storage device of a first embodiment. The semiconductor storage device of the first embodiment has a memory cell array 1 and a plurality of stepped portions 2 provided in a peripheral region positioned outside the memory cell array 1. The memory cell array 1 and the plurality of the stepped portions 2 are provided on the same substrate 10.

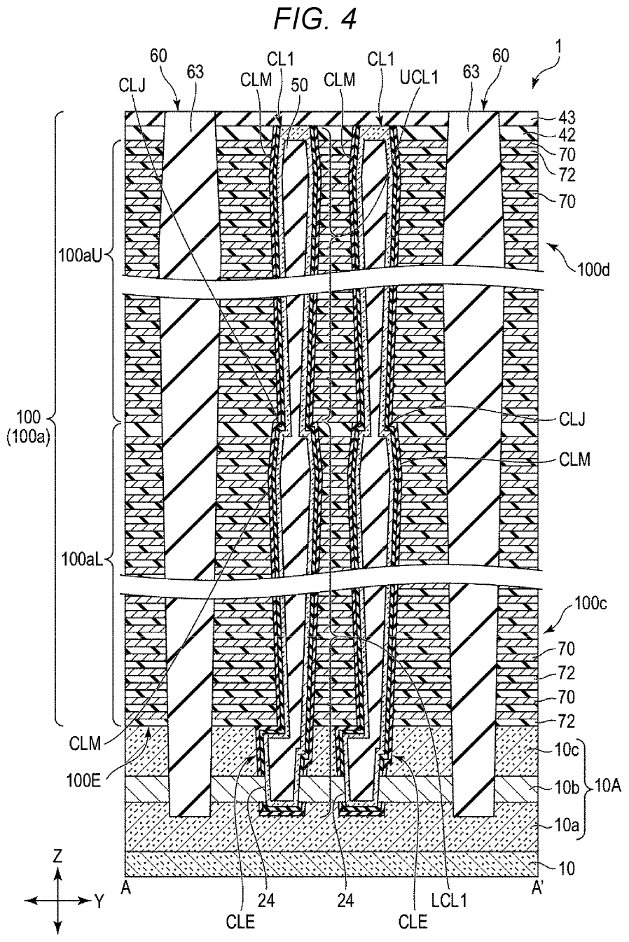

FIG. 2 is a schematic plan view showing a memory cell array 1 and the stepped portion 2 of a semiconductor storage device of a first embodiment. FIG. 3 is a schematic perspective view showing a memory cell array 1 of the first embodiment. FIG. 4 is a sectional view taken along line A-A′ including the stacked body 100 and the columnar portion CL1 in FIG. 2.

As shown in FIGS. 2 to 4, the memory cell array 1 includes a part of the substrate 10, a part of the stacked body 100 provided on the substrate 10, a plurality of columnar portions CL1, a plurality of insulating portions 60, and an upper layer wiring provided above the stacked body 100. In FIG. 3, for example, a bit line BL is shown as the upper layer wiring.

The substrate 10 and the stacked body 100 are provided over a cell array region in which the memory cell array 1 is provided and a stepped region in which the stepped portion 2 is provided. In the stacked body 100, a portion provided in the cell array region is referred to as a first stacked portion 100a (see FIG. 3, FIG. 4, and the like). A plurality of columnar portions CL1 are disposed in the cell array region. The columnar portion CL1 has a columnar shape extending in the stacking direction (Z direction) in the first stacked portion 100a.

In the present disclosure, the expression that the columnar portion such as the columnar portion CL1 extends in the Z direction means that the columnar portion may include a portion that extends in a direction different from the Z direction as long as the columnar portion extends in the Z direction as a whole.

As shown in FIG. 2, the plurality of columnar portions CL1 are, for example, arranged in a staggered manner. Alternatively, the plurality of columnar portions CL1 may be arranged in a square grid pattern along the X direction and the Y direction. The insulating portion 60 extends in the cell array region and the stepped region in the X direction, and divides the stacked body 100 into a plurality of string units 200 in the Y direction. Each string unit 200 has a cell array region and a stepped region.

As shown in FIG. 3, a plurality of bit lines BL are provided above the first stacked portion 100a. The plurality of bit lines BL are, for example, metal films extending in the Y direction. The plurality of bit lines BL are separated from each other in the X direction. An upper end of a semiconductor body 20, which will be described later, of the columnar portion CL1 is connected to the bit line BL via a contact Cb and a contact V1. A plurality of columnar portions CL1 are connected to one common bit line BL. The plurality of columnar portions CL1 connected to the common bit line BL include the columnar portions CL1 from each of the string units 200 separated in the Y direction by the insulating portion 60.

As shown in FIG. 4, the first stacked portion 100a has a plurality of conductive layers 70 stacked on the substrate 10. The plurality of conductive layers 70 are stacked in a direction (Z direction) perpendicular to an upper surface of the substrate 10 with insulating layers 72 interposed therebetween. The conductive layer 70 is, for example, a metal layer. The conductive layer 70 is, for example, a tungsten layer containing tungsten as a main component or a molybdenum layer containing molybdenum as a main component. The conductive layer 70 may be formed of a conductive material such as polysilicon doped with impurities. The insulating layer 72 is, for example, a silicon oxide layer containing silicon oxide as a main component.

In FIG. 3, the first stacked portion 100a is drawn as a simple stacked structure of the conductive layers 70 and the insulating layers 72, but in order to achieve higher stacking of the semiconductor storage device, as shown in FIG. 4, the first stacked portion 100a has a structure in which a plurality of tiers are vertically stacked in the Z direction.

As shown in FIG. 4, the first stacked portion 100a has a tiered structure having two tiers, that is, a lower tier portion 100aL and an upper tier portion 100aU.

The lower tier portion 100aL has a lower stacked body 100c having a stacked structure of the conductive layer 70 and the insulating layer 72. The lower stacked body 100c is provided with a plurality of lower layer columnar portions LCL1 penetrating the lower stacked body 100c in the Z direction.

The upper tier portion 100aU has an upper stacked body 100d having a stacked structure of the conductive layer 70 and the insulating layer 72. The upper stacked body 100d is provided with a plurality of upper layer columnar portions UCL1 penetrating the upper stacked body 100d in the Z direction.

As described above, the columnar portion CL1 has a stacked structure of the lower layer columnar portion LCL1 and the upper layer columnar portion UCL1, and a joint portion CLJ is formed at a boundary portion therebetween.

As shown in FIG. 4, both the lower layer columnar portion LCL1 and the upper layer columnar portion UCL1 have a columnar shape with a diameter that is small on the side close to the substrate 10 and that gradually increases in a direction (Z direction) away from the substrate 10. Each of the lower layer columnar portion LCL1 and the upper layer columnar portion UCL1 has a large-diameter portion CLM in which the diameter is at a maximum at a position slightly lower than the top. Each of the lower layer columnar portion LCL1 and the upper layer columnar portion UCL1 has a columnar shape with a diameter that gradually decreases from the large-diameter portion CLM to an upper portion side.

In the following description, regarding the columnar portion CL1 having a stacked structure of the lower layer columnar portion LCL1 and the upper layer columnar portion UCL1, in a case where the function and structure can be described as one columnar portion CL1, the columnar portion CL1 is simply referred to as the columnar portion CL1 and is used in the description.

The substrate 10 is, for example, a semiconductor substrate such as a silicon substrate. A wiring layer region 10A is provided on the substrate 10. The wiring layer region 10A has, for example, a semiconductor layer 10a, a source line 10b, and a semiconductor layer 10c, which are stacked on the substrate 10. A lower end portion CLE of the lower layer columnar portion LCL1 is embedded in the semiconductor layer 10a, the source line 10b, and the semiconductor layer 10c. That is, the lower end portion CLE of the lower layer columnar portion LCL1 is embedded in the wiring layer region 10A. The detailed structure of the lower end portion CLE of the lower layer columnar portion LCL1 will be described later.

The semiconductor layers 10a and 10c are made of n-type silicon or the like, which is formed as a result of adding impurities to a semiconductor such as silicon as a conductive material. The semiconductor layers 10a and 10c are made of, for example, phosphorus-doped polysilicon. A part of the film is removed from the lower end portion of the lower layer columnar portion LCL1, and the lower end portion is connected to the source line 10b, as will be described later. The source line 10b is made of a semiconductor layer or a conductive layer such as tungsten or tungsten silicide.

The insulating layer 72 is provided on an upper surface of the semiconductor layer 10c. The lowermost conductive layer 70 is provided on the insulating layer 72, and thereafter the insulating layer 72 and the conductive layer 70 are alternately stacked. An insulating layer 42 is provided on the uppermost conductive layer 70, and an insulating layer 43 is provided on the insulating layer 42. The insulating layer 43 covers an upper end of the columnar portion CL1.

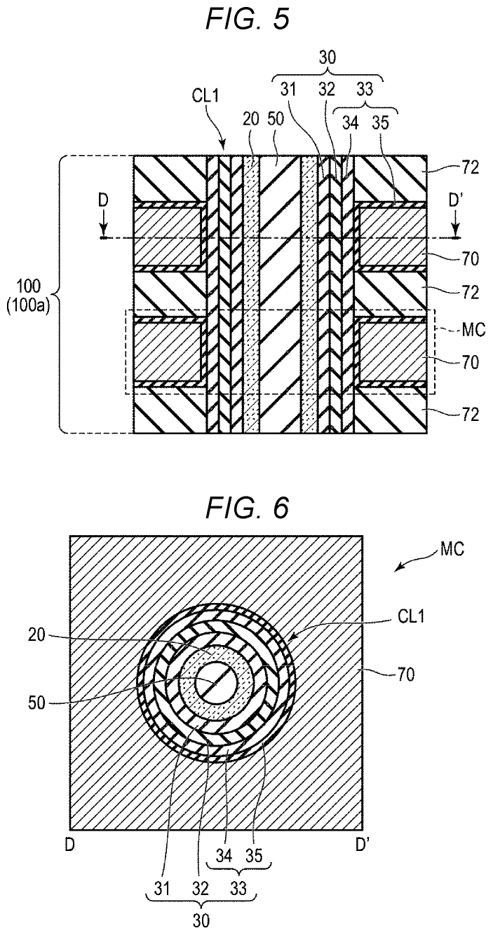

FIG. 5 is an enlarged sectional view of the columnar portion CL1 and a peripheral portion thereof in FIG. 4. FIG. 6 is a sectional view taken along line D-D′ in FIG. 5. The columnar portion CL1 has a stacked film (also referred to herein as a memory film) 30, the semiconductor body 20, and an insulating core portion 50.

The semiconductor body 20 extends continuously in an annular shape in the first stacked portion 100a in the stacking direction (Z direction). The stacked film 30 is provided between the conductive layer 70 and the semiconductor body 20 and between the insulating layer 72 and the semiconductor body 20, and surrounds the semiconductor body 20 from the outer peripheral side. The core portion 50 is provided inside the annular semiconductor body 20. The upper end side of the semiconductor body 20 is connected to the bit line BL via the contact Cb and the contact V1 shown in FIG. 3.

The stacked film 30 has a tunnel insulating film 31, a charge storage film 32, and a block insulating film 33. The tunnel insulating film 31, the charge storage film 32, and the block insulating film 33 are provided in this order from the semiconductor body 20 side between the semiconductor body 20 and the conductive layer 70. The charge storage film 32 is provided between the tunnel insulating film 31 and the block insulating film 33.

In the lower end portion CLE of the lower layer columnar portion LCL1, parts of the tunnel insulating film 31, the charge storage film 32, and the block insulating film 33 are partially removed in a region in contact with the source line 10b. Accordingly, a connection portion 24 (FIG. 4) is formed on a part of a side surface of the semiconductor body 20. The semiconductor body 20 is in direct contact with the source line 10b at the connection portion 24 facing the source line 10b.

The semiconductor body 20, the stacked film 30, and the conductive layer 70 form a memory cell MC. The memory cell MC has a vertical transistor structure in which the semiconductor body 20 is surrounded by the conductive layer 70 through the stacked film 30.

In the memory cell MC having a vertical transistor structure, the semiconductor body 20 is, for example, a silicon channel body, and the conductive layer 70 functions as a control gate. The charge storage film 32 functions as a data storage layer that stores charges injected from the semiconductor body 20.

The semiconductor storage device of the present embodiment is a nonvolatile semiconductor storage device. The memory cell MC is, for example, a charge trap type memory cell. The charge storage film 32 has a large number of trap sites for capturing charges in an insulating film, and includes, for example, a silicon nitride film. Alternatively, the charge storage film 32 may be a conductive floating gate surrounded by an insulator.

The tunnel insulating film 31 serves as a potential barrier when the charge is injected from the semiconductor body 20 into the charge storage film 32 or when the charge stored in the charge storage film 32 is released to the semiconductor body 20. The tunnel insulating film 31 contains a silicon oxide film, for example.

The block insulating film 33 prevents the release of the charge stored in the charge storage film 32 to the conductive layer 70. In addition, the block insulating film 33 prevents the charge back tunneling from the conductive layer 70 to the columnar portion CL1.

The block insulating film 33 has, for example, a first block film 34 and a second block film 35. The first block film 34 is, for example, a silicon oxide film. The second block film 35 is a metal oxide film having a higher dielectric constant than the silicon oxide film. Examples of the metal oxide film include an aluminum oxide film, a zirconium oxide film, and a hafnium oxide film.

The first block film 34 is provided between the charge storage film 32 and the second block film 35. The second block film 35 is provided between the first block film 34 and the conductive layer 70. The second block film 35 is also provided between the conductive layer 70 and the insulating layer 72. The second block film 35 is continuously formed along an upper surface, a lower surface, and a side surface on the stacked film 30 side of the conductive layer 70. The second block film 35 is not continuous in the stacking direction of the first stacked portion 100a, and is separated.

In addition, the second block film 35 may be continuously formed along the stacking direction of the first stacked portion 100a without being forming between the conductive layer 70 and the insulating layer 72. Alternatively, the block insulating film 33 may be a single-layer film that is continuous along the stacking direction of the first stacked portion 100a.

In addition, a metal nitride film may be formed between the second block film 35 and the conductive layer 70 or between the insulating layer 72 and the conductive layer 70. The metal nitride film is, for example, a titanium nitride film and can function as a barrier metal, an adhesion layer, and a seed metal of the conductive layer 70.

As shown in FIG. 3, a drain side select transistor STD is provided in an upper tier portion (an upper end portion of the columnar portion CL1) of the first stacked portion 100a. A source side select transistor STS is provided in the lower tier portion 100aL of the first stacked portion 100a. At least the uppermost conductive layer 70 functions as a control gate of the drain side select transistor STD. At least the lowermost conductive layer 70 functions as a control gate of the source side select transistor STS.

A plurality of memory cells MC are provided between the drain side select transistor STD and the source side select transistor STS. The plurality of memory cells MC, the drain side select transistor STD, and the source side select transistor STS are connected in series through the semiconductor body 20 of the columnar portion CL1 and form one memory string. The memory string is disposed, for example, in a staggered manner in a plane direction parallel to the XY plane. The plurality of memory cells MC are provided three-dimensionally in the X direction, the Y direction, and the Z direction.

### Structure of Lower End Portion of Lower Layer Columnar Portion

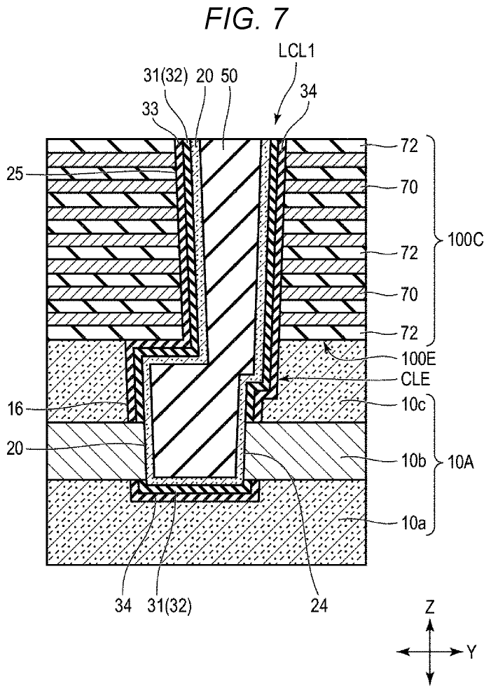

FIG. 7 shows an enlarged cross section of the lower end portion CLE of the lower layer columnar portion LCL1. Such an enlarged cross section may be acquired using, for example, a transmission electron microscope. The lower stacked body 100c has an end portion 100E facing the wiring layer region 10A as an end portion in the Z direction. The lower end portion CLE of the lower layer columnar portion LCL1 penetrates the end portion 100E in the Z direction and is embedded in the wiring layer region 10A.

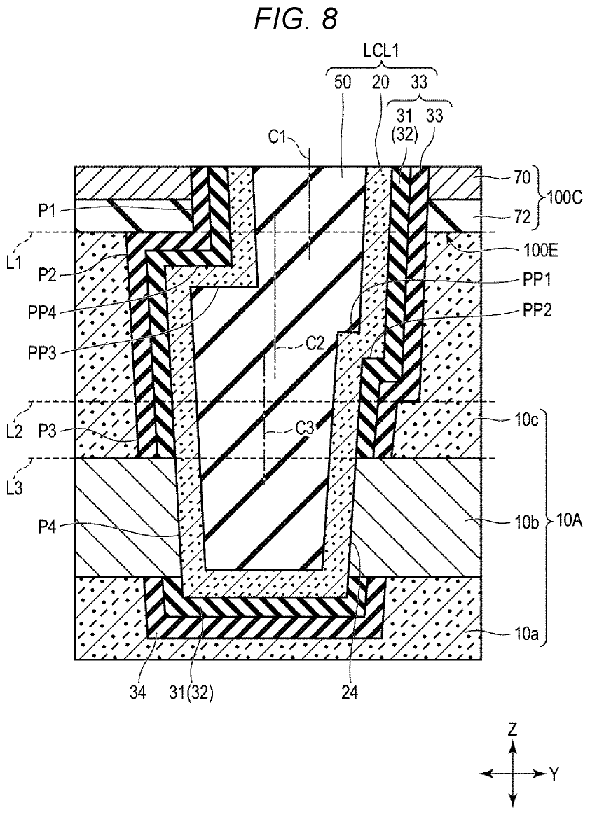

As shown in FIG. 8, the lower end portion CLE shown in FIG. 7 includes a first columnar portion P1, a second columnar portion P2, a third columnar portion P3, and a fourth columnar portion P4.

The first columnar portion P1 is positioned on the end portion 100E side of the lower stacked body 100c. The first columnar portion P1 is provided in the lower stacked body 100c.

The second columnar portion P2 is positioned closer to the substrate than the first columnar portion P1. The second columnar portion P2 is a portion of the lower layer columnar portion LCL1 between the broken line L1 and the broken line L2 in FIG. 8. The diameter of the second columnar portion P2 is larger than the diameter of the first columnar portion P1.

The third columnar portion P3 is positioned closer to the substrate than the second columnar portion P2. The third columnar portion P3 is a portion of the lower layer columnar portion LCL1 between the broken line L2 and the broken line L3 in FIG. 8. The second columnar portion P2 and the third columnar portion P3 are provided in the semiconductor layer 10c. The diameter of the third columnar portion P3 is smaller than the diameter of the second columnar portion P2.

The fourth columnar portion P4 is provided below the third columnar portion P3. The fourth columnar portion P4 extends to a position penetrating the source line 10b. The semiconductor body 20 is formed to surround a peripheral surface to a bottom surface of the fourth columnar portion P4.

In a portion of the fourth columnar portion P4 embedded in the source line 10b, the tunnel insulating film 31, the charge storage film 32, and the first block film 34 are removed, and the connection portion 24 of the semiconductor body 20 is formed. The semiconductor body 20 is in direct contact with the source line 10b in the connection portion 24. The tunnel insulating film 31, the charge storage film 32, and the first block film 34 are formed around a portion of the lower end portion of the fourth columnar portion P4, which is surrounded by the semiconductor layer 10a.

In the example in FIG. 8, with respect to a first axis C1 that penetrates the center of an upper surface (X-Y plane) of the first columnar portion P1 in the Z direction, a second axis C2 that penetrates the center of an upper surface of the second columnar portion P2 in the Z direction deviates in the −Y direction (toward the left side) with respect to the Y direction. With respect to a third axis C3 that penetrates the center of an upper surface of the third columnar portion P3 in the Z direction, the second axis C2 deviates in the +Y direction (toward the right side) with respect to the Y direction. In addition, with respect to the first axis C1, the third axis C3 deviates in the −Y direction (toward left side) with respect to the Y direction.

The semiconductor body 20 of the second columnar portion P2 includes an extending portion PP1 extending in the Y direction. In addition, the charge storage film 32 of the second columnar portion P2 includes an extending portion PP2 extending in the Y direction. The second extending portion PP2 is positioned closer to the substrate than the first extending portion PP1. The second extending portion PP2 is in contact with the first extending portion PP1. A channel is formed in the first extending portion PP1 on an interface side with the second extending portion PP2 in the Y direction.

The semiconductor body 20 of the second columnar portion P2 further includes an extending portion PP3 extending in the Y direction. The third extending portion PP3 is positioned closer to the lower stacked body 100c than the first extending portion PP1. In addition, the charge storage film 32 of the second columnar portion P2 further includes an extending portion PP4 extending in the Y direction. The fourth extending portion PP4 is positioned closer to the lower stacked body 100c than the third extending portion PP3. The fourth extending portion PP4 is in contact with the third extending portion PP3. A channel is formed in the third extending portion PP3 on an interface side with the fourth extending portion PP4 in the Y direction. The region in which the second channel is formed is positioned closer to the lower stacked body 100c than the region in which the first channel is formed.

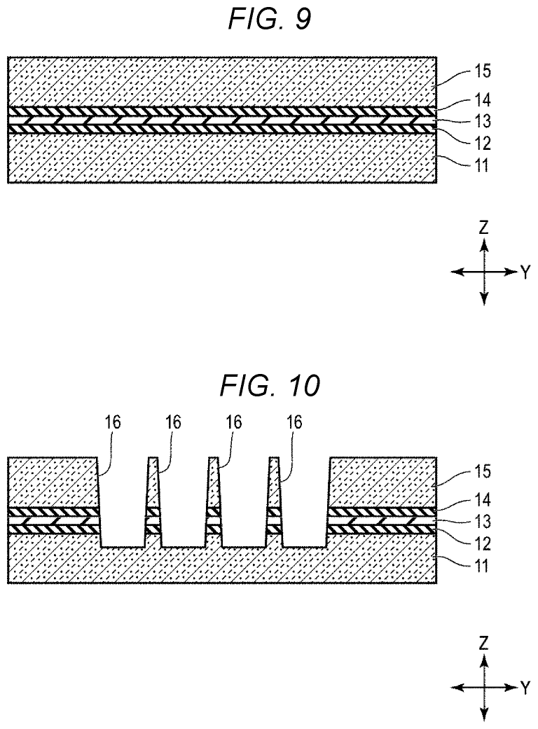

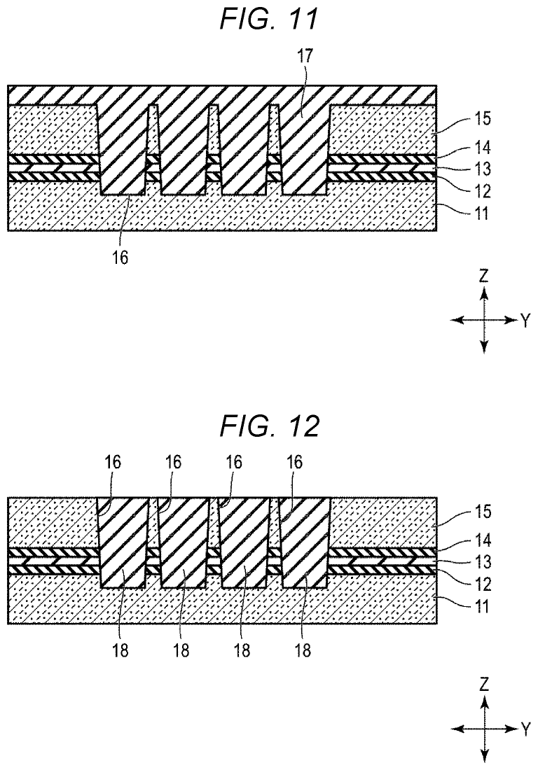

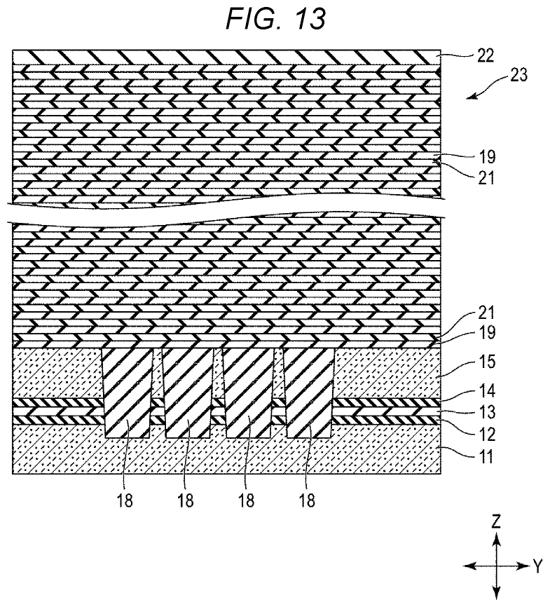

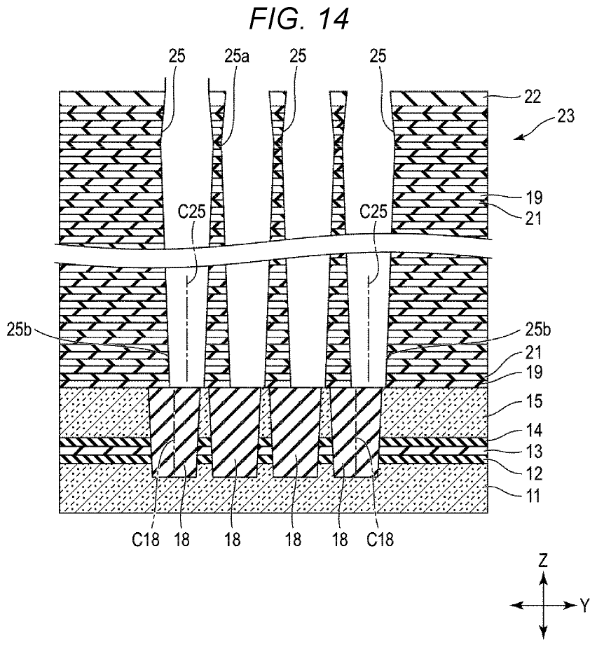

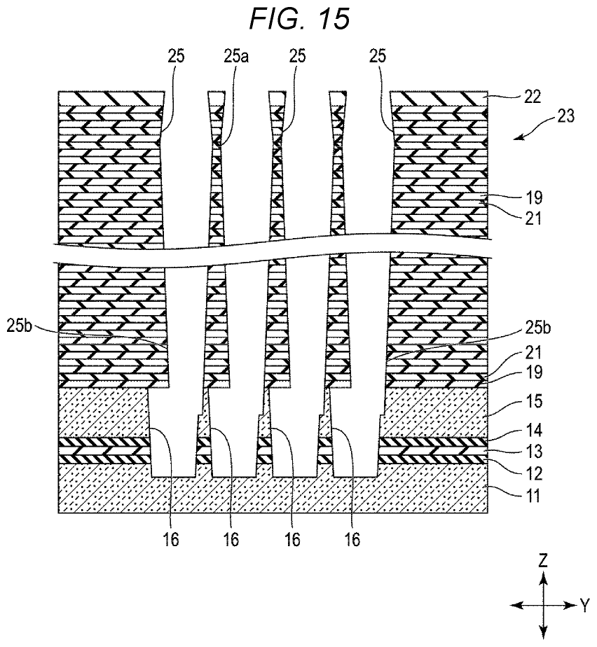

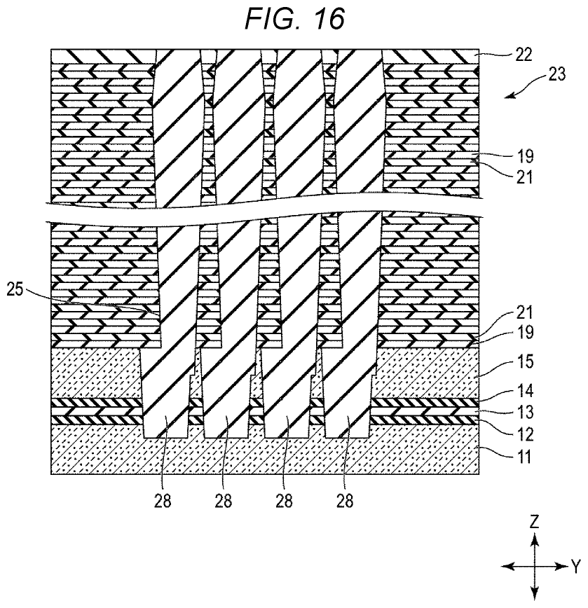

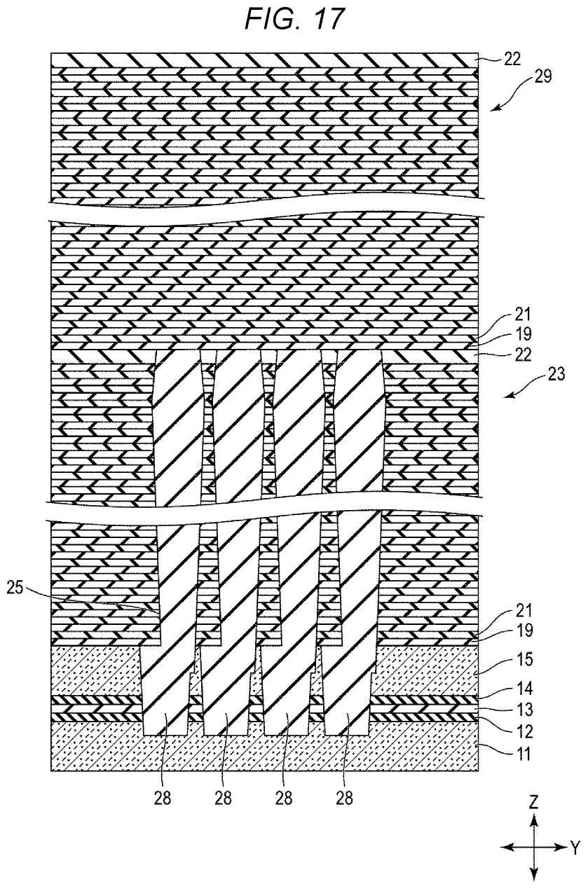

The structure of the present embodiment is obtained by using a manufacturing method including a step of forming a stopper material 18 and a lower stacked body 23 (FIGS. 12 and 13), a step of forming a lower memory hole 25 reaching the stopper material 18 in the lower stacked body 23 such that a part of a surface of a semiconductor layer 15 is exposed (FIG. 14), and a step of removing the stopper material 18 by etching and removing a part of the surface of the semiconductor layer 15 (FIG. 15) as described below with reference to, for example, FIGS. 9 to 22.

In a case where a bottom memory hole 16 is formed in advance in the wiring layer region 10A and then the lower stacked body 100c is formed on the wiring layer region 10A, an effect of not unnecessarily increasing the inner diameter of the lower memory hole 25 formed in the lower stacked body 100c as described below is obtained. This effect will be described in association with the manufacturing method to be described later.

Next, the configuration of the insulating portion 60 will be described. As shown in FIGS. 2 and 4, the insulating portion 60 has an insulating film 63. In addition, in FIG. 3, the insulating film 63 is not shown. The insulating film 63 extends in the X direction and the Z direction. For example, as shown in FIG. 4, the insulating film 63 is adjacent to the first stacked portion 100a to extend in the Z direction and to reach an upper portion side of the semiconductor layer 10a. As described above, the lower end portion of the semiconductor body 20 in the columnar portion CL1 shown in FIG. 4 is in contact with the source line 10b.

Next, an outline of the stepped portion 2 will be described. The stepped portion 2 is also separated by the insulating portion 60 and is a part of the string unit 200. The stepped portion 2 is provided with a columnar body CL3 and a contact portion CT, and is provided with a terrace portion 70a.

### Manufacturing Method of First Embodiment

Next, a manufacturing method of a semiconductor storage device according to the first embodiment will be described with reference to FIGS. 9 to 22. Cross sections of FIGS. 9 to 22 correspond to the cross section of FIG. 4.

A semiconductor layer 11, a protective layer 12, a sacrificial layer 13, a protective layer 14, and the semiconductor layer 15 are stacked on the substrate 10, which is not shown in FIG. 9. The semiconductor layer 11 is, for example, a polycrystalline silicon layer doped with phosphorus. The protective layers 12 and 14 are, for example, a silicon oxide film. The sacrificial layer 13 is, for example, an undoped polycrystalline silicon layer. The semiconductor layer 15 is, for example, an undoped polycrystalline silicon layer or a polycrystalline silicon layer doped with phosphorus.

As shown in FIG. 10, a plurality of bottom memory holes 16 are formed. In the present embodiment, as shown in FIG. 2, the plurality of columnar portions CL1 are formed in a staggered manner, so that the bottom memory hole 16 is formed to correspond to the position where the columnar portion CL1 is formed. The bottom memory hole 16 may be formed by an etching method such as reactive ion etching. The bottom memory hole 16 penetrates the semiconductor layer 15, the protective layer 14, the sacrificial layer 13, and the protective layer 12, and has a depth that reaches the semiconductor layer 11 at a predetermined depth.

The inner diameter of an upper end portion of the bottom memory hole 16 is formed to be larger than the inner diameter of a lower end portion of the lower memory hole 25 to be formed on the bottom memory hole 16 later.

As shown in FIG. 11, a stopper material layer 17 is formed to be embedded in the bottom memory hole and cover an upper surface of the semiconductor layer 15. A carbon film or the like may be applied to the stopper material layer 17. The material of the stopper material layer 17 is preferably a material having a high etching selection ratio with respect to the lower stacked body 23 that includes the stacked body of an insulating layer 19 and a sacrificial layer 21 to be formed later.

As shown in FIG. 12, the etching back is performed to remove the stopper material layer 17 stacked on the semiconductor layer 15, and only the stopper material layer 17 embedded in the bottom memory hole 16 is left. Accordingly, the bottom memory hole 16 is embedded with the stopper material 18.

As shown in FIG. 13, the insulating layer 19 and the sacrificial layer 21 are alternately stacked to form a lower stacked body 23 in which an insulating layer 22 is formed on the uppermost sacrificial layer 21. The insulating layers 19 and 22 are, for example, silicon oxide films, and the sacrificial layer 21 is, for example, a silicon nitride film.

As shown in FIG. 14, the lower memory hole 25 is formed so that a part of the surface of the semiconductor layer 15 is exposed with respect to the lower stacked body 23. The lower memory hole 25 may be formed using an etching method such as reactive ion etching using a mask (not shown) formed on the insulating layer 22. In the present embodiment, the center C25 of the lower memory hole 25 is positioned to deviate from the center C18 of the stopper material 18 in the +Y direction such that a part of the surface of the semiconductor layer 15 is exposed. Hereinafter, the degree of the positional deviation is referred to as an MH deviation amount.

The stopper material 18 is removed by a method such as ashing through the lower memory hole 25, and the lower memory hole 25 and the bottom memory hole 16 communicate with each other. In this method, only the stopper material 18 is removed, and the inner diameter of the lower memory hole 25 is not unnecessarily increased. Thereafter, the semiconductor layers 11 and 15 exposed on an inner surface of the bottom memory hole 16 are oxidized to form silicon oxide layers (not shown).

On the other hand, it is conceivable to assume a manufacturing method in which the lower stacked body 23 is formed on the semiconductor layer 15 in the state shown in FIG. 9 in which the bottom memory hole 16 is not formed, and the lower memory hole reaching the semiconductor layer 11 from an upper surface of the lower stacked body 23 is formed.

This manufacturing method is a method of creating a deep lower memory hole reaching the semiconductor layer 11 from the upper surface of the lower stacked body 23 only by etching without providing the stopper material 18.

However, in a case where this method is adopted, the enlarged inner diameter portion 25a of the lower memory hole 25 may be larger than expected due to variations in etching conditions and the like.

In this case, it is conceivable that the interval between the adjacent lower memory holes 25 and 25 is narrower than expected, and the formation of the columnar portion in the subsequent step may be hindered. In addition, there is a concern that this phenomenon may prevent a further increase in the density of memory cells and a further reduction in the chip size. That is, in a case where the interval between the lower memory holes 25 is reduced, the adjacent lower memory holes 25 may come into contact with each other, which causes a problem in further increasing the density of the memory cells and further reducing the chip size.

On the other hand, in a case where a method of removing the stopper material 18 after forming the lower memory hole 25 is adopted using the above-described stopper material 18, a problem of the enlarged inner diameter portion 25a being larger than expected is unlikely to occur, and thus a structure that is able to accommodate further increase in the density of the memory cells and reduction of the chip size can be provided.

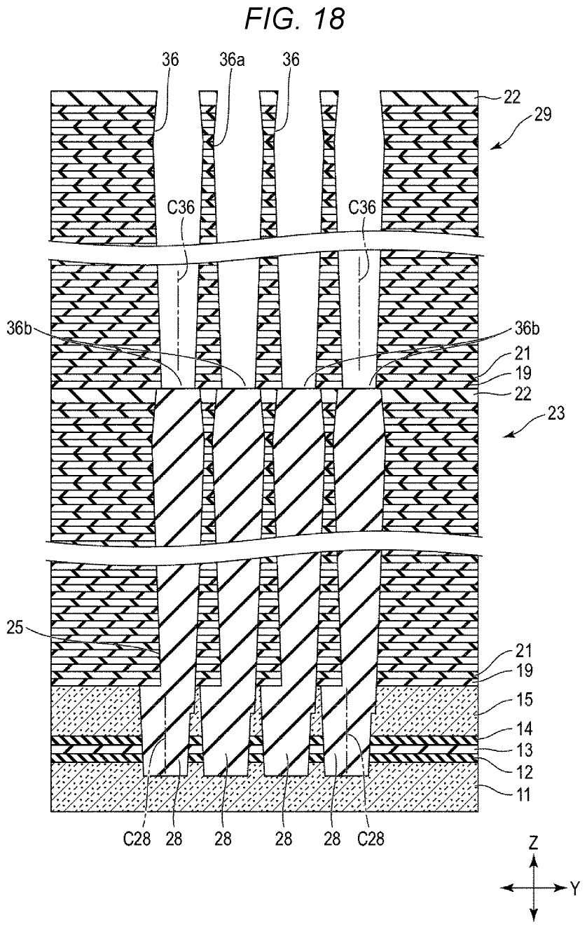

After the semiconductor layers 11 and 15 exposed on the inner surface of the bottom memory hole 16 are oxidized to form the silicon oxide layers (not shown), a filling material 28 is formed to be embedded in the bottom memory hole 16 and the lower memory hole 25, as shown in FIG. 16. A carbon film or the like may be applied to the filling material 28.

As shown in FIG. 17, an upper stacked body 29 is formed on the lower stacked body 23. The structure of the upper stacked body 29 is the same as the configuration of the lower stacked body 23, in which the insulating layer 19 and the sacrificial layer 21 are alternately stacked, and the insulating layer 22 is formed on the uppermost sacrificial layer 21.

As shown in FIG. 18, an upper memory hole 36 is formed from a top portion to a bottom portion of the upper stacked body 29 to correspond to the formation position of the lower memory hole 25 with respect to the upper stacked body 29. The upper memory hole 36 may be formed by an etching method such as reactive ion etching.

The upper memory hole 36 has a shape in which the inner diameter is gradually reduced toward a lower end portion side, and an enlarged inner diameter portion 36a is formed at a position slightly lower than the upper end of the upper memory hole 36. The lower end portion 36b of the upper memory hole 36 reaches an upper end portion of the filling material 28.

Here, due to an error or the like in the position alignment accuracy when forming the upper memory hole 36, the center C36 of the upper memory hole 36 and the center C28 of the columnar filling material 28 may be positioned to deviate in the Y direction (left-right direction) of FIG. 18.

The upper memory hole 36 is a position where the upper layer columnar portion UCL1 is provided, and the lower memory hole 25 is a position where the lower layer columnar portion LCL1 is provided. Therefore, in order to obtain the columnar portion CL1 in which the upper layer columnar portion UCL1 and the lower layer columnar portion LCL1 are reliably joined, it is important to have a configuration in which the upper memory hole 36 and the lower memory hole 25 can reliably communicate with each other.

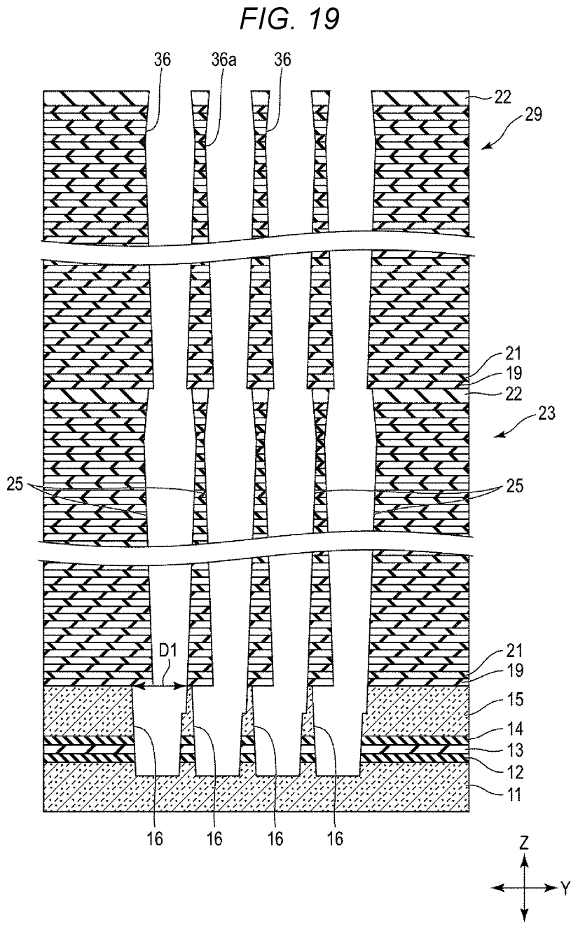

As shown in FIG. 19, the filling material 28 of the lower memory hole 25 and the bottom memory hole 16 is removed by a method such as ashing via the upper memory hole 36. Accordingly, the upper memory hole 36, the lower memory hole 25, and the bottom memory hole 16 communicate with each other. In the above-described step of removing the carbon film by a method such as ashing, only the filling material 28 can be removed. Therefore, the upper memory hole 36 and the lower memory hole 25 having the desired inner diameter can be obtained without unnecessarily increasing the inner diameters of the upper memory hole 36 and the lower memory hole 25. In addition, in the present embodiment, the diameter D1 of an opening of the bottom memory hole 16 increases by a size corresponding to the magnitude of the MH deviation amount generated in FIG. 14, compared to the case where there is no MH deviation amount.

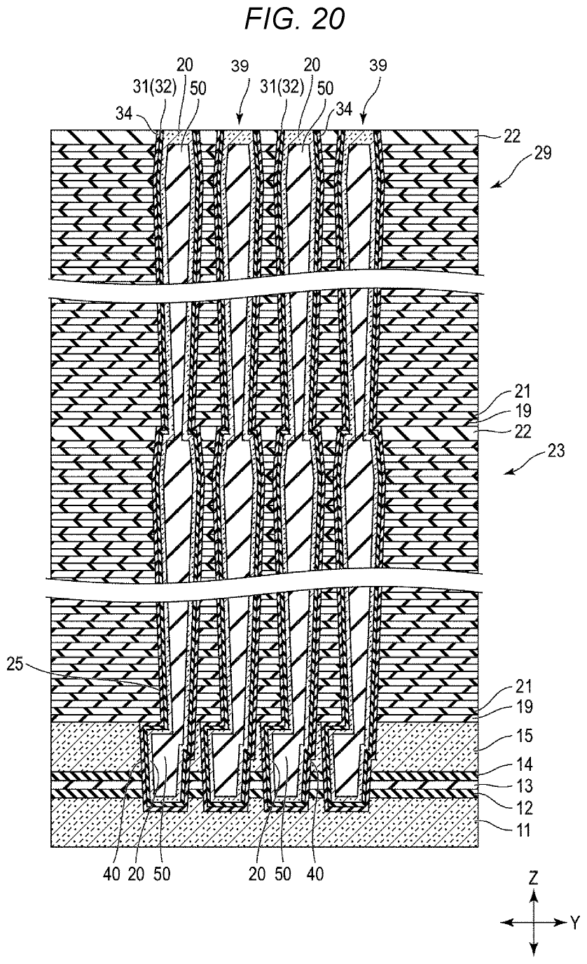

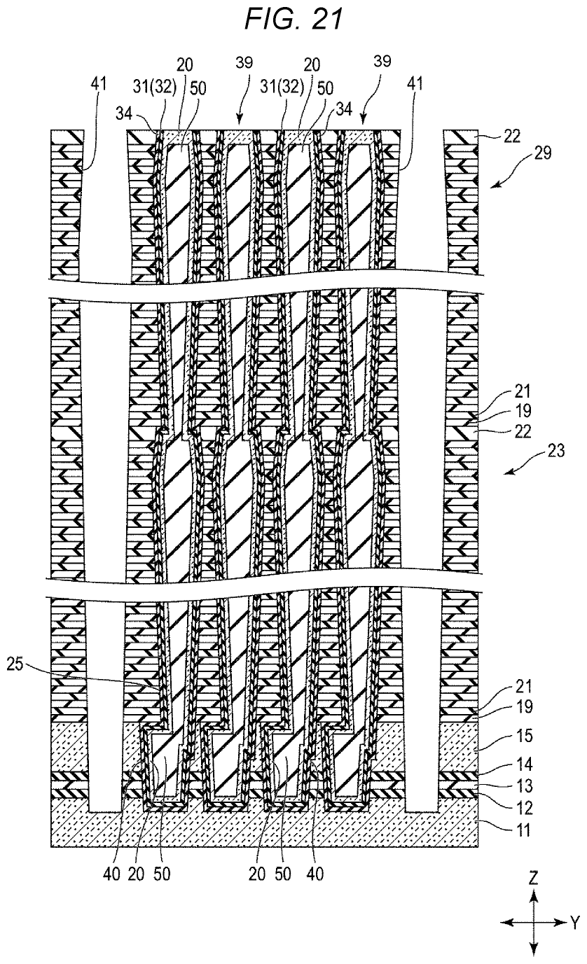

A film formation is performed in the bottom memory hole 16, the lower memory hole 25, and the upper memory hole 36 shown in FIG. 19. That is, as shown in FIG. 20, the first block film 34, the charge storage film 32, the tunnel insulating film 31, the semiconductor body 20, and the core portion 50 are formed. Also, an upper layer base columnar portion serving as a base of the upper layer columnar portion UCL1 and a lower layer base columnar portion serving as a base of the lower layer columnar portion LCL1 are formed. Both the upper layer base columnar portion and the lower layer base columnar portion may be collectively referred to as a base columnar portion 39. In FIG. 20, for the sake of simplification of the drawing, the charge storage film 32 and the tunnel insulating film 31 are drawn as one layer of film. Similarly, the charge storage film 32 and the tunnel insulating film 31 may also be drawn as one layer of film in other drawings.

Here, when an amorphous semiconductor film (for example, a phosphorus-doped amorphous silicon film) including an impurity to be the semiconductor body 20 is formed in the holes 16, 25, and 36, and the amorphous semiconductor film is heated to be changed to a polycrystalline semiconductor film, the semiconductor film is contracted by heat. Even in a case where the semiconductor film is contracted by heat, the opening diameter D1 increases as described in the description of FIG. 19, and thus it is possible to prevent the occurrence of a void (a portion not embedded with the semiconductor film) at a boundary portion between the hole 16 and the hole 25 due to the step of the semiconductor film. As a result, it is possible to improve the electrical characteristics of the semiconductor storage device.

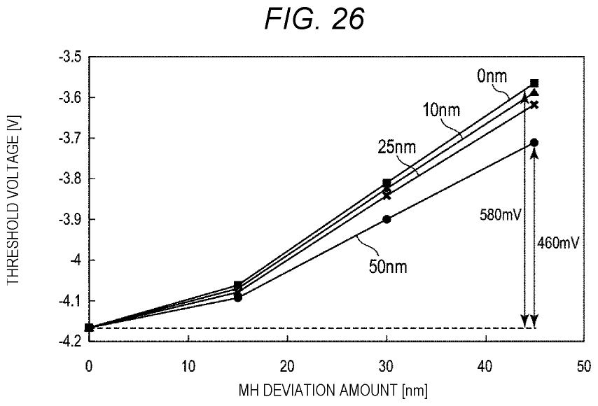

In addition, as shown in FIG. 26, according to the research of the present inventors, it was discovered that the larger the MH deviation amount, the more the variation in the threshold voltage of the transistor (for example, the source side select transistor) can be prevented.

FIG. 26 shows the variation in the threshold voltage when the MH deviation amount is 50 nm (Example 1) and when the MH deviation amount is 0 nm (Example 2). As shown, the variation in the threshold voltage of Example 1 is smaller than the variation in the threshold voltage of Example 2. For example, with reference to the threshold voltage of the black square in FIG. 26, the variation of Example 1 was 460 mV, but the variation of Example 2 was 580 mV.

As described above, it is possible to improve the electrical characteristics of the semiconductor storage device by being able to prevent the variation in the threshold voltage of the transistor.

It is considered that one of the reasons why the larger the MH deviation amount, the variation in the threshold voltage can be prevented more is that the variation in the concentration distribution of the impurities in the semiconductor film is reduced. The variation in the concentration distribution of the impurities in the semiconductor film is reduced, so that the impurities are contained in the semiconductor body 20 at the boundary portion between the hole 16 and the hole 25.

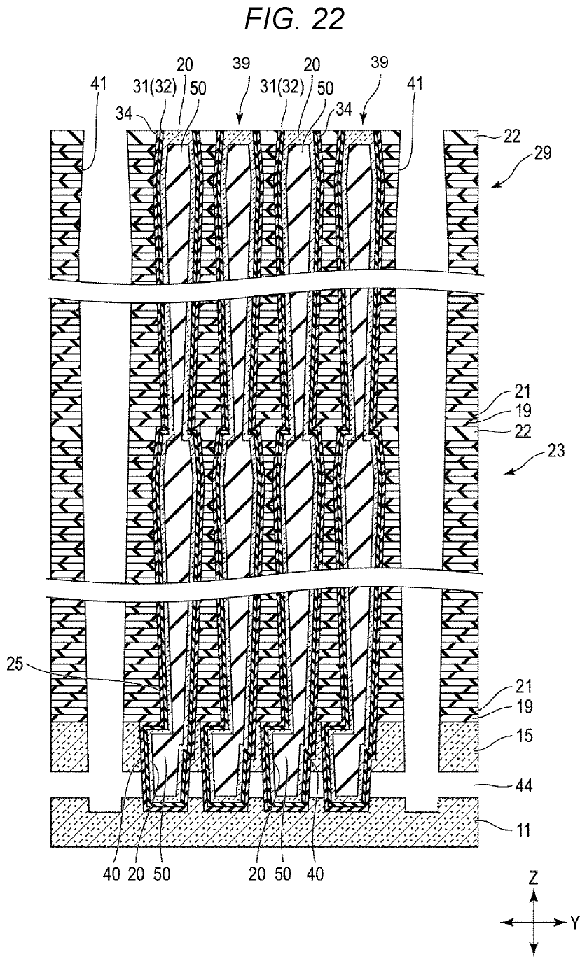

As shown in FIG. 21, for example, slits 41 are formed on both sides of the four base columnar portions 39 in the Y direction (left-right direction). The slit 41 may be formed by an etching method such as reactive ion etching. The slit 41 is formed to penetrate the upper stacked body 29 and the lower stacked body 23 in the Z direction and reach the semiconductor layer 11. The slit 41 penetrates the semiconductor layer 15, the protective layer 14, the sacrificial layer 13, and the protective layer 12, and has a depth that reaches the semiconductor layer 11 at a predetermined depth.

As shown in FIG. 22, an etching processing using an etchant is performed through the slit 41 to remove the protective layer 14, the sacrificial layer 13, and the protective layer 12 and to form a cavity portion 44.

From the state shown in FIG. 22, a liner film (not shown) is formed on an inner surface of the slit 41, and a large-diameter portion 40 formed at a lower end portion of the lower layer base columnar portion exposed in the cavity portion 44 is etched. By this etching, the first block film 34, the charge storage film 32, and the tunnel insulating film 31 on the outer peripheral side of the large-diameter portion 40 are removed. By this etching, the semiconductor body 20 can be exposed in the cavity portion 44.

Thereafter, when a semiconductor layer is formed to be embedded in the cavity portion 44, the source line 10b shown in FIG. 4 can be formed. Therefore, the wiring layer region 10A having the semiconductor layer 10a, the source line 10b, and the semiconductor layer 10c can be formed.

After the formation of the wiring layer region 10A, the sacrificial layer 21 stacked in the lower stacked body 23 and the upper stacked body 29 is removed by removing the liner film and performing etching through the slit 41. The sacrificial layer 21 can be removed by an etchant or an etching gas supplied through the slit 41, and a cavity can be formed in the portion where the sacrificial layer 21 is formed.

By forming the second block film 35 and the conductive layer 70 in the cavity, a structure equivalent to the structure shown in FIGS. 4 to 6 can be manufactured.

After the sacrificial layer is removed through the slit 41, the steps up to forming the conductive layer are known in this type of three-dimensional memory.

### Second Embodiment

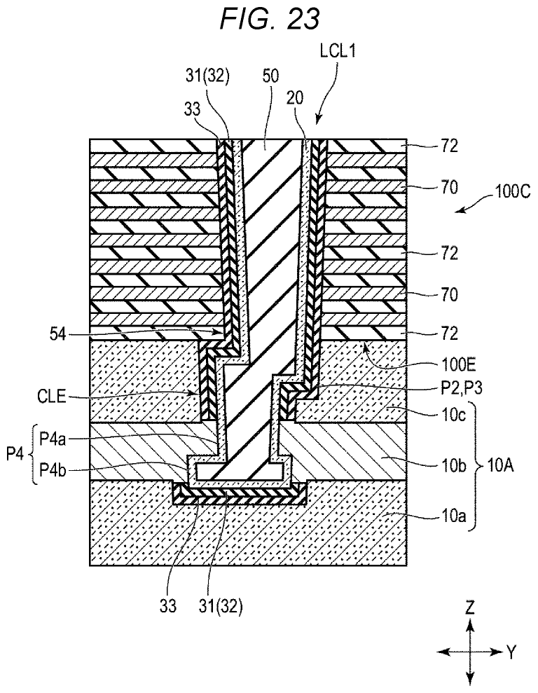

FIG. 23 shows a structure of a semiconductor storage device of a second embodiment. The semiconductor storage device of the present embodiment is different from the semiconductor storage device of the first embodiment in that a fourth columnar portion P4 including a small-diameter columnar portion P4a and a large-diameter columnar portion P4b is provided in the source line 10b of the wiring layer region 10A.

In the fourth columnar portion P4, the large-diameter columnar portion P4b is positioned closer to the substrate than the small-diameter columnar portion P4a. The large-diameter columnar portion P4b has a larger diameter than the small-diameter columnar portion P4a.

In addition, lower surfaces of the charge storage film 32 and the block insulating film 33 in the portion surrounded by the semiconductor layer 10c are positioned in the +Z direction (slightly above) with respect to the lower surface of the semiconductor layer 10c. At this location, the source line 10b of the portion in contact with a lower surface of the stacked film extends slightly in the +Z direction.

Upper surfaces of the charge storage film 32 and the block insulating film 33 in the portion surrounded by the semiconductor layer 10a are positioned in the −Z direction (slightly lower) with respect to an upper surface of the semiconductor layer 10a. At this location, the source line 10b of the portion in contact with the upper surface of the stacked film extends slightly in the −Z direction.

In FIG. 23, a side surface of the fourth columnar portion P4 in the source line 10b is not covered with the tunnel insulating film 31, the charge storage film 32, and the block insulating film 33, but a structure in which the side surface of the fourth columnar portion P4 is covered with the tunnel insulating film 31, the charge storage film 32, and the block insulating film 33 may be adopted.

According to the present embodiment, the contact area between the source line 10b and the lower layer columnar portion LCL1 can be increased as a result of the presence of the large-diameter columnar portion P4b, and it is possible to prevent a decrease in contact resistance between the source line 10b and the lower layer columnar portion LCL1 as a result of miniaturization.

### Third Embodiment

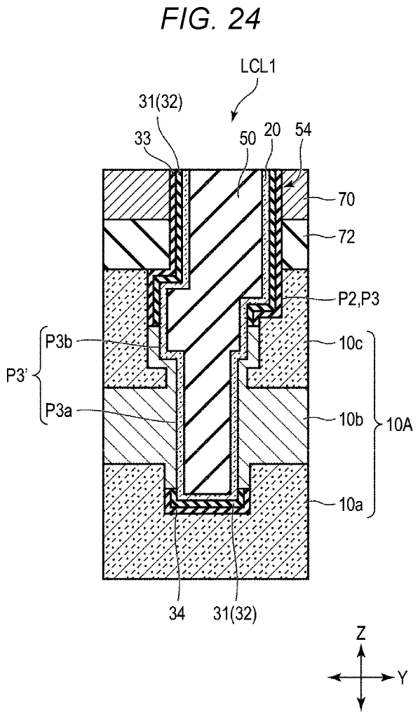

FIG. 24 shows a structure of a semiconductor storage device of a third embodiment. The semiconductor storage device of the present embodiment is different from the semiconductor storage device of the first embodiment in that a third columnar portion P3′ is provided in the semiconductor layer 10a, the source line 10b, and the semiconductor layer 10c of the wiring layer region 10A.

The third columnar portion P3′ is positioned closer to the substrate than the second columnar portion P2. The third columnar portion P3′ and the second columnar portion P2 are connected to each other. In FIG. 24, a side surface of the third columnar portion P3′ is not covered with the tunnel insulating film 31, the charge storage film 32, and the block insulating film 33, but a structure in which the side surface of the third columnar portion P3′ is covered with the tunnel insulating film 31, the charge storage film 32, and the block insulating film 33 may be adopted.

The third columnar portion P3′ includes a small-diameter columnar portion P3a and a large-diameter columnar portion P3b. The small-diameter columnar portion P3a is positioned closer to the substrate than the large-diameter columnar portion P3b. The large-diameter columnar portion P3b has a larger diameter than the small-diameter columnar portion P3a. The presence of the small-diameter columnar portion P3a and the large-diameter columnar portion P3b causes the diameter of the third columnar portion P3′ in the semiconductor layer 10a, the source line 10b, and the semiconductor layer 10c to change discontinuously in the Z direction.

In addition, the lower surfaces of the charge storage film 32 and the block insulating film 33 in the portion surrounded by the semiconductor layer 10c are positioned in the +Z direction (above) with respect to the lower surface of the semiconductor layer 10c. At this location, the source line 10b of the portion in contact with the lower surface of the stacked film extends in the +Z direction.

The upper surfaces of the charge storage film 32 and the block insulating film 33 in the portion surrounded by the semiconductor layer 10a are positioned in the −Z direction (below) with respect to the upper surface of the semiconductor layer 10a. At this location, the source line 10b of the portion in contact with the upper surface of the stacked film extends in the −Z direction.

According to the present embodiment, the contact area between the source line 10b and the lower layer columnar portion LCL1 can be increased as a result of the presence of the large-diameter columnar portion P3b, and it is possible to prevent a decrease in contact resistance between the source line 10b and the lower layer columnar portion LCL1 due to miniaturization.

### Fourth Embodiment

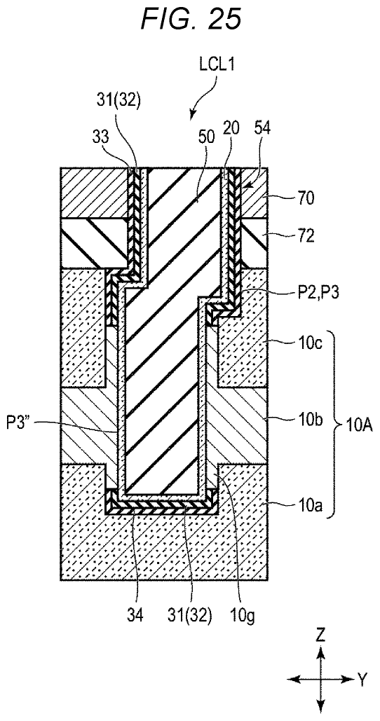

FIG. 25 shows a structure of a semiconductor storage device of a fourth embodiment. The semiconductor storage device of the present embodiment is different from the semiconductor storage device of the third embodiment in that one third columnar portion P3″ having a large diameter is provided instead of the third columnar portion P3′ of the third embodiment. The diameter of the third columnar portion P3″ is selected to be greater than or equal to the designed contact resistance between the source line 10b and the lower layer columnar portion LCL1. The diameter of the third columnar portion P3″ may continuously change in the Z direction, or may be constant in the Z direction.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a substrate;
a wiring layer region provided on the substrate;
a stacked body that is provided on the wiring layer region and in which a plurality of conductive layers and a plurality of insulating layers are alternately stacked in a first direction; and
a columnar portion that extends in the first direction through the stacked body and into the wiring layer region, the columnar portion including a semiconductor body extending in the first direction through the stacked body and into the wiring layer region and a charge storage film surrounding the semiconductor body and extending in the first direction through the stacked body and into the wiring layer region, wherein
the stacked body has an end portion in the first direction facing the wiring layer region,
the columnar portion includes a first columnar portion positioned at the end portion of the stacked body, a second columnar portion provided in the wiring layer region, and a connection portion between the first columnar portion and the second columnar portion,
the semiconductor body in the connection portion having a first extending portion that extends in a second direction crossing the first direction, and the charge storage film in the connection portion having a second extending portion that extends in the second direction and covers the first extending portion in the first direction.

2. The semiconductor storage device according to claim 1, wherein
the wiring layer region includes first and second semiconductor layers and a conductive layer between the first and second semiconductor layers, and
a part of the semiconductor body in the second columnar portion is in direct contact with the conductive layer.

3. The semiconductor storage device according to claim 1, wherein
the semiconductor body in the connection portion further includes a third extending portion that extends in a direction opposite to the second direction, and
the charge storage film in the connection portion further includes a fourth extending portion that extends in the direction opposite to the second direction and covers the third extending portion in the first direction.

4. The semiconductor storage device according to claim 1, wherein
a center axis of the first columnar portion and a center axis of the second columnar portion deviate in the second direction.

5. The semiconductor storage device according to claim 4, wherein
the columnar portion further includes a third columnar portion that is provided in the wiring layer region, is positioned closer to the substrate than the second columnar portion, and does not include the charge storage film, and
the third columnar portion includes a small-diameter columnar portion and a large-diameter columnar portion that has a diameter larger than that of the small-diameter columnar portion and is positioned closer to the substrate than the small-diameter columnar portion.

6. The semiconductor storage device according to claim 5, wherein
the wiring layer region includes first and second semiconductor layers and a conductive layer between the first and second semiconductor layers, and
the semiconductor body in the third columnar portion is in direct contact with the conductive layer.

7. The semiconductor storage device according to claim 6, wherein a length of a contact surface between the conductive layer in the third columnar portion and the conductive layer in the first direction is greater than a thickness of the conductive layer where the conductive layer is sandwiched by the first and second semiconductor layers in the first direction.

8. The semiconductor storage device according to claim 1, wherein
the columnar portion further includes a third columnar portion that is provided in the wiring layer region and that is positioned closer to the substrate than the second columnar portion, and a diameter of the third columnar portion is smaller than a diameter of the second columnar portion.

9. The semiconductor storage device according to claim 8, wherein
the wiring layer region includes first and second semiconductor layers and a conductive layer between the first and second semiconductor layers, and
the semiconductor body in the third columnar portion is in direct contact with the conductive layer.

10. The semiconductor storage device according to claim 9, wherein a length of a contact surface between the conductive layer in the third columnar portion and the conductive layer in the first direction is greater than a thickness of the conductive layer where the conductive layer is sandwiched by the first and second semiconductor layers in the first direction.

11. A semiconductor storage device comprising:
a substrate;
a wiring layer region provided on the substrate;
a stacked body that is provided on the wiring layer region and in which a plurality of conductive layers and a plurality of insulating layers are alternately stacked in a first direction; and
a columnar portion that extends in the first direction through the stacked body and into the wiring layer region, the columnar portion including a semiconductor body extending in the first direction through the stacked body and into the wiring layer region and a charge storage film surrounding the semiconductor body and extending in the first direction through the stacked body and into the wiring layer region, wherein
the stacked body has an end portion in the first direction facing the wiring layer region,
the columnar portion includes a first columnar portion positioned at the end portion of the stacked body, a second columnar portion provided in the wiring layer region, and a connection portion between the first columnar portion and the second columnar portion, and
a center axis of the first columnar portion is offset with respect to a center axis of the second columnar portion in a second direction crossing the first direction.

12. The semiconductor storage device according to claim 11, wherein a diameter of the semiconductor body in the first columnar portion is less than a diameter of the semiconductor body in the second columnar portion.

13. The semiconductor storage device according to claim 12, wherein
the wiring layer region includes first and second semiconductor layers and a conductive layer between the first and second semiconductor layers, and
a part of the semiconductor body in the second columnar portion is in direct contact with the conductive layer.

14. The semiconductor storage device according to claim 13, wherein a length of a contact surface between the conductive layer in the third columnar portion and the conductive layer in the first direction is about equal to a thickness of the conductive layer where the conductive layer is sandwiched by the first and second semiconductor layers in the first direction.

15. The semiconductor storage device according to claim 11, wherein
the columnar portion further includes a third columnar portion that is provided in the wiring layer region, is positioned closer to the substrate than the second columnar portion, and does not include the charge storage film, and
the third columnar portion includes a small-diameter columnar portion and a large-diameter columnar portion that has a diameter larger than that of the small-diameter columnar portion and is positioned closer to the substrate than the small-diameter columnar portion.

16. The semiconductor storage device according to claim 15, wherein
the wiring layer region includes first and second semiconductor layers and a conductive layer between the first and second semiconductor layers, and
the semiconductor body in the third columnar portion is in direct contact with the conductive layer.

17. The semiconductor storage device according to claim 16, wherein a length of a contact surface between the conductive layer in the third columnar portion and the conductive layer in the first direction is greater than a thickness of the conductive layer where the conductive layer is sandwiched by the first and second semiconductor layers in the first direction.

18. The semiconductor storage device according to claim 11, wherein
the columnar portion further includes a third columnar portion that is provided in the wiring layer region, is positioned closer to the substrate than the second columnar portion, and does not include the charge storage film, and
a diameter of the third columnar portion is smaller than a diameter of the second columnar portion.

19. The semiconductor storage device according to claim 18, wherein
the wiring layer region includes first and second semiconductor layers and a conductive layer between the first and second semiconductor layers, and
a part of the semiconductor body in the second columnar portion and the entire semiconductor body in the third columnar portion are in direct contact with the conductive layer.

20. The semiconductor storage device according to claim 19, wherein a length of a contact surface between the conductive layer in the second and third columnar portions and the conductive layer in the first direction is greater than a thickness of the conductive layer where the conductive layer is sandwiched by the first and second semiconductor layers in the first direction.
